(19) United States
(12) Patent Application Publication
(10) Pub. No.: US 2011/0204487 A1
(43) Pub. Date: Aug. 25, 2011

(54) SEMICONDUCTOR DEVICE AND ELECTRONIC APPARATUS

(75) Inventors: TAKAHIRO NAKANO, Kyoto (JP); MASAKI UTSUMI, Kyoto (JP); HIKARI SANO, Hyogo (JP)

(73) Assignee: PANASONIC CORPORATION, Osaka (JP)

(21) Appl. No.: 13/100,398

(22) Filed: May 4, 2011

Related U.S. Application Data
(63) Continuation-in-part of application No. PCT/JP2009/006218, filed on Nov. 19, 2009.

(30) Foreign Application Priority Data
Nov. 25, 2008 (JP) 2008-299443
Dec. 26, 2008 (JP) 2008-333133

(51) Int. Cl. H01L 23/48

(52) U.S. Cl. 257/621; 257/E23.011

(57) ABSTRACT

A semiconductor device includes: a semiconductor substrate; a through electrode passing through the semiconductor substrate in a thickness direction of the semiconductor substrate; an internal electrode provided in a part of the top surface of the semiconductor substrate and electrically connected to the through electrode which reaches the part; a first protective film covering the top surface except a part of the internal electrode; a second protective film formed apart from the first protective film, on the part of the internal electrode, the part being not covered by the first protective film; and metal wiring formed on the back surface of the semiconductor substrate and electrically connected to the through electrode, the second main surface being on a side of the semiconductor substrate opposite the first main surface.

### CROSS REFERENCE TO RELATED APPLICATION

This is a Continuation-in-Part application of PCT application No. PCT/JP2009/006218 filed on Nov. 19, 2009, designating the United States of America, the contents of which are incorporated herein by reference.

### BACKGROUND

(1) Technical Field

The technical field relates to a semiconductor device and an electronic apparatus.

(2) Description of the Related Art

In order to reduce the size, thickness, and weight of electronic apparatuses and achieve packaging thereof in a high density, many semiconductor devices manufactured using techniques of wafer-level chip size packaging (CSP) which enables fabrication processing at wafer level, have been used in recent electronic apparatus.

For example, solid-state imaging devices, which are typical to optical devices, are used as photosensors in digital imaging apparatuses, such as digital still cameras, cameras built in mobile phones, and digital camcorders. In order to achieve such reduction of the size, thickness, and weight of imaging apparatuses and packaging thereof in a high density, techniques of the wafer-level CSP have been used for manufacturing the solid-state imaging devices instead of techniques of ceramic-type or plastic-type packaging. The ceramic-type packaging and the plastic-type packaging ensure electrical connection between inside and outside the apparatuses by die bonding and wire bonding. On the other hand, in the techniques for the wafer-level CSP, the electrical connection between inside and outside the apparatuses are ensured by forming through electrodes and rewiring in fabrication processing on wafers before dicing (for example, see Japanese Unexamined Patent Application Publication Number 2004-207461 and Japanese Unexamined Patent Application Publication Number 2007-123909).

FIG. 1 is a cross-sectional view of a solid-state imaging device which has a conventional wafer-level CSP structure.

As shown in FIG. 1, a conventional solid-state imaging device 100A includes an imaging area 102, a peripheral circuit area 104A, and a solid-state imaging element 100 including a plurality of electrodes 104B. The imaging area 102 is located on a semiconductor substrate 101 and has a plurality of microlenses on a main surface, which is a light-receiving surface, of the semiconductor substrate 101. The peripheral circuit area 104A is formed in a surrounding area of the imaging area 102 on the main surface. The electrodes 104B are connected to the peripheral circuit area 104A.

In addition, a transparent substrate 106 made of, for example, optical glass, is formed above the main surface of the semiconductor substrate 101 with a bonding member 105 made of resin interposed therebetween. In addition, in the semiconductor substrate 101, through electrodes 107 are formed which passes through the semiconductor substrate 101 in the thickness direction of the semiconductor substrate 101.

On a back surface, which is opposite to the main surface of the semiconductor substrate 101, metal wiring 108 and an insulating resin layer 109 are formed. The metal wiring 108 is connected to the electrodes 104B of the peripheral circuit area 104A via the through electrodes 107. Part of the metal wiring 108 is covered by the insulating resin layer 109, and the rest of the metal wiring 108 is exposed in openings 110 in the insulating resin layer 109. In each of the openings 110, an external electrode 111 made of, for example, a solder material is formed.

Note that the solid-state imaging element 100 is electrically insulated from the through electrodes 107 and the metal wiring 108 by an insulating layer not shown in FIG. 1.

As described above, in the conventional solid-state imaging device 100A, the electrodes 104B are electrically connected to the metal wiring 108 via the through electrodes 107, and further to the external electrodes 111 via the metal wiring 108, thus allowing light-reception signals to be taken out.

The conventional solid-state imaging device 100A is manufactured through a process exemplified below.

(Step 1) Form a plurality of solid-state imaging elements 100 having the above-described structure on a wafer using a known method. The transparent substrate 106, which is made of, for example, optical glass and has the same shape as the wafer, is attached to the wafer having the solid-state imaging elements 100 formed thereon, with the bonding member 105 made of a resin layer interposed between the wafer and the transparent substrate 106.

(Step 2) Form through holes in the wafer by dry etching or wet etching from the back surface of the wafer. The through holes pass through the semiconductor substrate 101, and the electrodes 104B of the peripheral circuit area 104A are exposed in the through holes. Then, a conductive material is implanted in the through holes to form the through electrodes 107 connecting to the electrode 104B which allows light-reception signals to be taken out.

(Step 3) Form the metal wiring 108 on the back surface of the solid-state imaging elements 100 by electroplating in a manner such that the metal wiring 108 electrically connects to the through electrodes 107.

(Step 4) Form the insulating resin layer 109 on the back surface of the solid-state imaging elements 100 so as to cover the metal wiring 108. Typically, the insulating resin layer 109 is made of photosensitive resin and formed by spin-coating or applying a dry film.

(Step 5) Remove the insulating resin layer 109 selectively by a photolithographic technique (exposure and developing) to form the openings 110 in which part of the metal wiring 108 is exposed.

(Step 6) Form the external electrodes 111 in the respective openings 110 by a solder ball mounting method using flux or a solder paste printing method in a manner such that the external electrodes 111 electrically connects to the metal wiring 108. The external electrodes 111 are made of, for example, a solder material.

(Step 7) Finally, dice the wafer into solid-state imaging devices, each of which is the solid-state imaging device 100A shown in FIG. 1, by cutting through the solid-state imaging elements 100, the bonding member 105, the transparent substrate 106, and the insulating resin layer 109 using a cutting tool, such as a dicing saw.

### SUMMARY

Manufactured using the techniques for the wafer-level CSP, such solid-state imaging devices contribute to reduction of the size, thickness, and weight of the electronic apparatuses, and increase in density of packaging. On the other hand, heat stress produced in the steps after forming of the through electrodes 107 or stress due to environmental load, such as heat in an environment of actual use, cause stress concentration of the through electrodes 107 on the electrodes 104B. This may cause problems such as improper connections and reliability degradation due to breaking or peel-off of the electrodes 104B, or detachment (fall-out) of the through electrodes.

Specifically, because of difference between the through electrode 107 and the electrode 104B in the rate of thermal expansion, a particularly large stress (heat stress) concentrates on the edge (circumference) of the contact area between the through electrode 107 and the electrode 104B, causing breaking or peel-off of the electrode 104B.

In view of the above problem, as well as other concerns, a solid-state imaging device has been presented for which measures are taken against such stress concentration (for example, see Japanese Unexamined Patent Application Publication Number 2008-140819 (Patent Reference 3)).

In the solid-state imaging device, a protective film (not shown) made of an inorganic insulating material is formed so as to cover the whole surface of the electrode 104B connected to the through electrodes 107 shown in FIG. 1 for the purpose of preventing improper connections such as breaking and peel-off of the electrodes 104B due to stress concentration of the through electrodes 107 on the electrodes 104B caused by temperature changes.

However, such breaking and peel-off of the electrodes 104B may still occur in the solid-state imaging device even when the durability of the electrodes 104B is increased as described above.

Specifically, the inorganic material for the protective film used in the above configuration is relatively hard so that not only the electrodes 104B but also the protective film are broken or detached when stress concentrates on the electrodes 104B in a configuration where such a hard protective film covers the surface of the electrodes 104B. This measure against stress concentration may not be effective enough.

In view of this a problem, a concern of the present disclosure is to provide a semiconductor device which is preferable for prevention of occurrence of improper connection and decrease in reliability with further increase in durability against breaking and peel-off of the electrodes 104B due to stress concentration of the through electrodes 107 on the electrodes 104B. Furthermore, another concern is to provide a semiconductor device with a configuration suitable for preventing detachment (fall-out) of through electrodes.

In order to achieve these concerns, a semiconductor device according to a first aspect includes: a semiconductor substrate; a through electrode passing or penetrating through the semiconductor substrate in a thickness direction of the semiconductor substrate; an internal electrode provided in a part of a first main surface of the semiconductor substrate and electrically connected to the through electrode which reaches the part; a first protective film covering the first main surface except a part of the internal electrode; a second protective film formed apart from the first protective film, on the part of the internal electrode, the part being not covered by the first protective film; and metal wiring formed on a second main surface of the semiconductor substrate and electrically connected to the through electrode, the second main surface being on a side of the semiconductor substrate opposite the first main surface.

Here, the second protective film is larger, in area, than a contact area between the through electrode and the internal electrode.

Furthermore, the second protective film may be circular or polygonal in shape. Furthermore, the second protective film is annular in shape and has an external diameter larger than a diameter of a contact area between the through electrode and the internal electrode and an internal diameter smaller than the diameter of the contact area.

Furthermore, each of the first protective film and the second protective film may include an inorganic material. Alternatively, the first protective film may include an inorganic material and the second protective film may include an organic material.

Furthermore, the semiconductor device may further include a third protective film formed on the internal electrode so as to fill part of a clearance between the first protective film and the second protective film.

Furthermore, the semiconductor device may further include an insulating layer covering the second main surface except a part of the metal wiring, and may further include an external electrode provided on the part of the metal wiring and electrically connected to the metal wiring, the area being not covered by the insulating layer.

In order to achieve the object, a semiconductor device according to a second aspect includes: a semiconductor substrate; a through electrode passing or penetrating through the semiconductor substrate in a thickness direction of the semiconductor substrate; an internal electrode provided in a part of a first main surface of the semiconductor substrate and electrically connected to the through electrode which reaches the part; a first protective film covering the first main surface and the internal electrode except a part of the internal electrode; and metal wiring formed on a second main surface of the semiconductor substrate and electrically connected to the through electrode, the second main surface being on a side of the semiconductor substrate opposite the first main surface, wherein a plurality of openings is formed in the protective film so as to be located on the internal electrode.

Furthermore, the plurality of openings may be formed outside of a contact area between the through electrode and the internal electrode.

Furthermore, each of the openings may be circular in shape. Furthermore, each of the openings may be a polygonal shape, and each of the openings having the polygonal shape may have rounded corners. Furthermore, each of the openings may have an arched contour.

Furthermore, on the internal electrode, the number of the openings in the protective film may be two or more. Furthermore, above the internal electrode, another protective film may be formed on the protective film, and the another protective film may contact the internal electrode through the plurality of openings. The another protective film may include an organic material or an inorganic material.

The semiconductor device may further include an insulating layer covering the second main surface except a part of the metal wiring, and may further include an insulating layer covering the second main surface except a part of the metal wiring.

Further, not only the semiconductor devices but also as an electronic apparatus may be implemented to in accordance with the above features.

The second protective film prevents deformation of the internal electrode even in the case where heat stress produced in steps after forming of the through electrodes or stress due to environmental load, such as heat in an environment of actual use, causes stress concentration of the through electrodes on the electrodes, so that improper connection due to breaking or peel-off of the internal electrode is prevented, thereby ensuring highly reliable connection.

The clearance, which is formed between the first protective film and the second protective film by forming them apart from each other, relaxes stress concentration on the internal electrode and stress due to deformation of the internal electrode, thereby ensuring prevention of breaking, cracking, and peel-off of the internal electrode.

Furthermore, the third protective films formed on part of the clearance between the first protective film and the second protective film not only allow the clearance remaining between the first protective film and the second protective film to relax stress concentration on the internal electrode and stress due to deformation of the internal electrode, but also transmit forces to prevent deformation of the internal electrode from the first protective film to the second protective film when stress concentration occurs, thereby preventing separation and fall-out of the through electrode toward the second main surface of the semiconductor substrate.

Furthermore, the first protective film and the second protective film formed as an integrated protective film in the area except part of the internal electrode allow the openings, in which the protective film is not formed, relax stress concentration on the internal electrode and stress due to deformation of the internal electrode, thereby ensuring prevention of breaking, cracking, and peel-off of the internal electrode.

Furthermore, another protective film formed on the protective file not only allows the openings to relax stress concentration of stress on the internal electrode and stress due to deformation of the internal electrode, but also prevents separation and fall-out of the through electrode toward the second main surface of the semiconductor substrate.

### FURTHER INFORMATION ABOUT TECHNICAL BACKGROUND TO THIS APPLICATION

The disclosure of Japanese Patent Application No. 2008-299443 filed on Nov. 25, 2008 including specification, drawings and claims is incorporated herein by reference in its entirety.

The disclosure of Japanese Patent Application No. 2008-333133 filed on Dec. 26, 2008 including specification, drawings and claims is incorporated herein by reference in its entirety.

The disclosure of PCT application No. PCT/JP2009/006218 filed on Nov. 19, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view of a conventional solid-state imaging device;

FIG. 2 is a cross-sectional view illustrating a structure of a semiconductor device according to an embodiment;

FIG. 3 is a set of a top view and a cross-sectional view illustrating a configuration of the second protective film;

FIG. 4 is a set of a top view and a cross-sectional view illustrating a configuration of the second protective film;

FIG. 5 is a set of a top view and a cross-sectional view illustrating a configuration of the second protective film;

FIGS. 6(A) and (B) is a set of top views each illustrating a configuration of the second protective film and the third protective film;

FIG. 7 is a set of a top view and a cross-sectional view illustrating a structure of a main part of the semiconductor device;

FIGS. 8(A) to (D) is a set of top views each illustrating a configuration of the protective film of the semiconductor device;

FIG. 9 is a cross-sectional view illustrating another structure of the main part of the semiconductor device;

FIG. 10 is a cross-sectional view illustrating a structure of the semiconductor device according to an exemplary embodiment; and

FIG. 11 is a cross-sectional view illustrating a structure of the semiconductor device according to another exemplary embodiment.

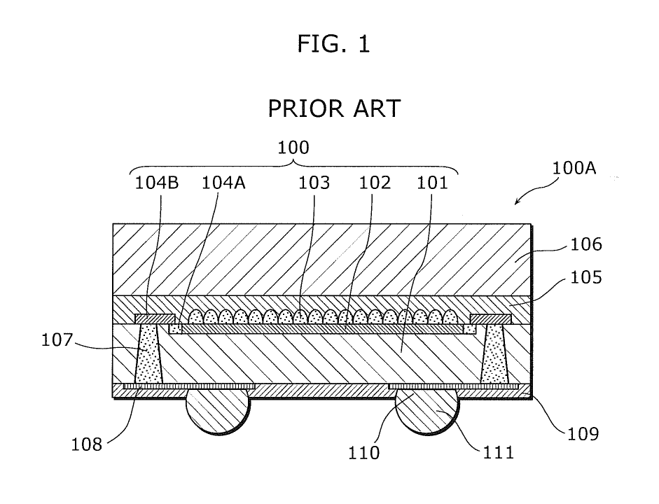

### DESCRIPTION OF THE PREFERRED EMBODIMENTS

The following will describe semiconductor devices according to various exemplary embodiments.

### Embodiment 1

First, a semiconductor device according to Embodiment 1 will be described with reference to the drawings.

(Structure of a Semiconductor Device)

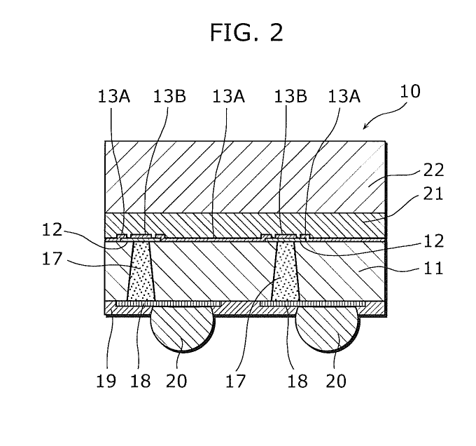

FIG. 2 is a cross-sectional view illustrating a structure of the semiconductor device 10 according to Embodiment 1.

As shown in FIG. 2, the semiconductor device 10 according to Embodiment 1 includes internal electrodes 12 formed on an upper one of the main surfaces (hereinafter referred to as a top surface) of a semiconductor substrate 11 shown in the drawing and mainly including a metal such as Al or Cu, a first protective film 13A and second protective films 13B. The first protective film 13A is formed on the main surface and a region of the internal electrodes 12 so that a first portion of the internal electrode is uncovered by the first protective film 13A. That is, the first protective film 13A covers a first main surface except a part of the surface of each of the internal electrodes 12. The second protective films 13B are formed on a region of the uncovered first portion of the internal electrodes so that a second portion of the internal electrodes is uncovered by the second protective film 13B. That is, the second protective films 13B are formed on parts where the internal electrodes 12 are not covered by the protective film 13A. The second protective films 13B are formed apart from the first protective film 13A.

Here, the first and second protective films 13A and 13B are generally called passivation and made of inorganic materials such as SiN. However, materials for the second protective film 13B are not limited to inorganic ones and may be made of an organic material and be made in steps different from steps of making the first protective film 13A.

In addition, the semiconductor device 10 includes through electrodes 17, metal wiring 18, and an insulating layer 19. The through electrodes 17 pass or penetrates through the semiconductor substrate 11 in the thickness direction of the semiconductor substrate 11 to reach lower ones of the surfaces (hereinafter referred to as back surfaces) of the internal electrodes 12, and electrically connect to the internal electrodes 12. The metal wiring 18 is formed on the lower one of the main surfaces (hereinafter referred to as a back surface) of the semiconductor substrate 11 shown in the drawing and electrically connected to the through electrodes 17. The insulating layer 19 covers the back surface of the semiconductor substrate 11 except a part of the surface of the metal wiring 18.

Each of the through electrodes 17 is formed by plating an inner wall of a through hole (not shown) formed in the semiconductor substrate 11 in advance (that is, surfaces of the semiconductor substrate 11 and the internal electrode 12 facing the through hole) with, for example, Cu or a metal material mainly including Cu, or by filling the through hole with conductive paste. Typical depths of the through hole are within a range of 10 μm to 300 μm. Each of the through electrodes 17 may fill the through hole or cover the inner wall of the through hole to form a film of a uniform thickness.

The metal wiring 18 is formed by plating the back surface of the semiconductor substrate 11 with, for example, Cu or a metal material mainly made of Cu. Preferable thicknesses of the metal wiring 18 are within a range of 5 μm to 20 μm.

In the parts of the metal wiring 18 not covered by the insulating layer 19, external electrodes 20, which are made of, for example, a lead-free solder material having a composition of Sn—Ag—Cu, are formed to electrically contact with the metal wiring 18.

In addition, a transparent substrate 22, which is made of, for example, optical glass or support glass, is formed above the top surface of the semiconductor substrate 11 with the protective films 13 and a bonding layer 21 interposed therebetween.

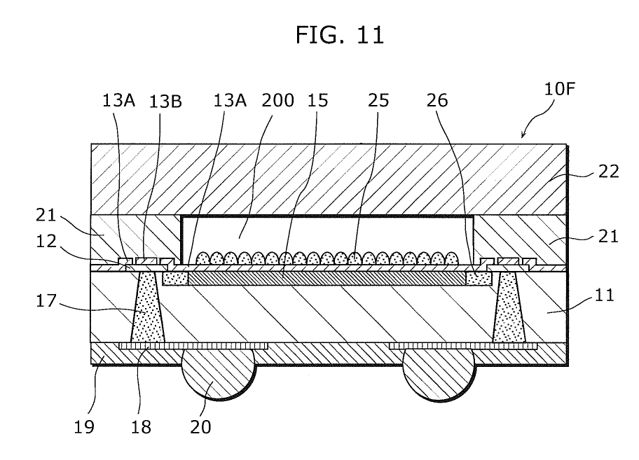

Here, the bonding layer 21 may cover the top surfaces of the semiconductor substrate 11, the first protective film 13A, and the second protective films 13B as in the semiconductor device 10 shown in FIG. 2, or have a cavity structure in which there is a hollow portion 200 in the bonding layer 21 and under the transparent substrate 22 as shown in FIG. 11.

The materials for the bonding layer 21 and the transparent substrate 22 are properly selected depending on purposes such as increase in electrical characteristics of the semiconductor substrate 11 or reinforcement of the semiconductor substrate.

Note that although the transparent substrate 22 is effective particularly when the semiconductor device is applied to an optical device or when it functions as a reinforcing plate to reinforce the semiconductor substrate 11, it is not an essential element for a structure of an end product and may be omitted.

The electrical connection between the internal electrode 12 and the external electrode 20 via the through electrode 17 and the metal wiring 18 allows signal exchange between the inside and the outside of the semiconductor device 10 via the internal electrode 12, the through electrode 17, the metal wiring 18, and the external electrode 20. Note that the semiconductor substrate 11 is electrically insulated from the through electrode 17 and the metal wiring 18 by an insulating film (not shown) made of, for example, SiO2.

(Detailed Structure of Main Part)

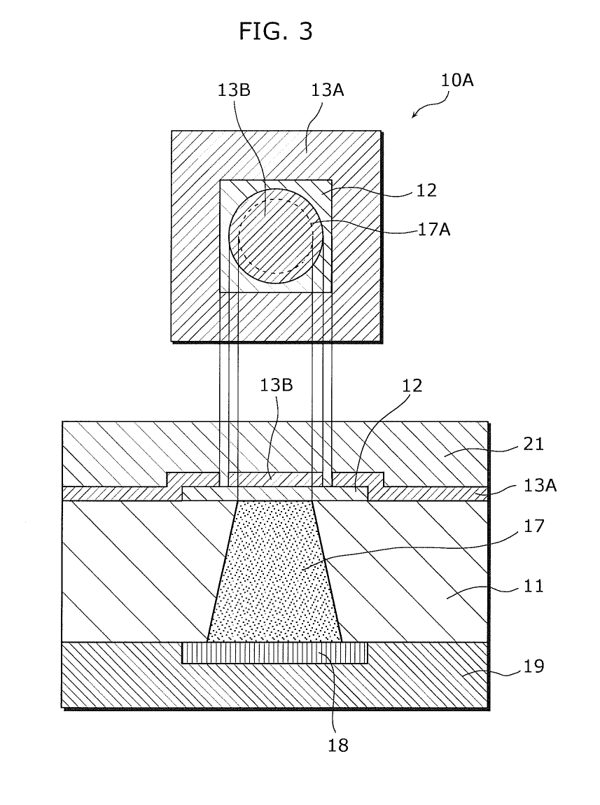

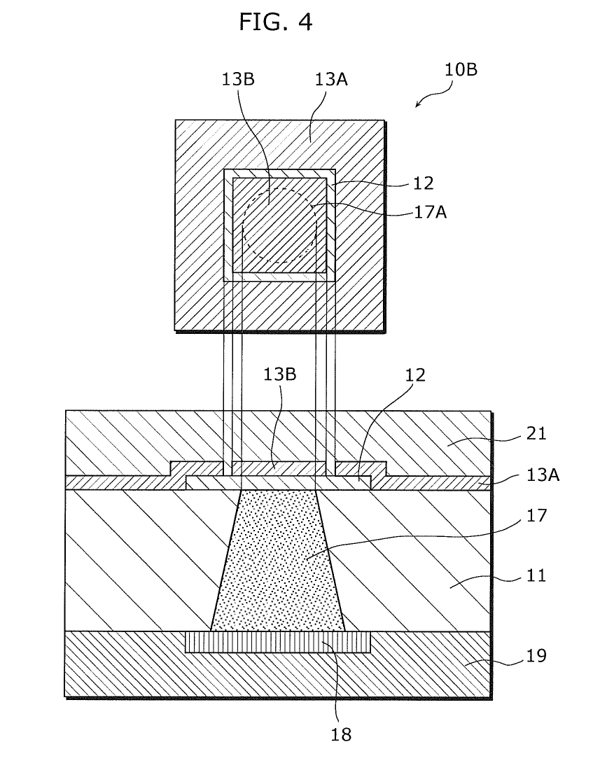

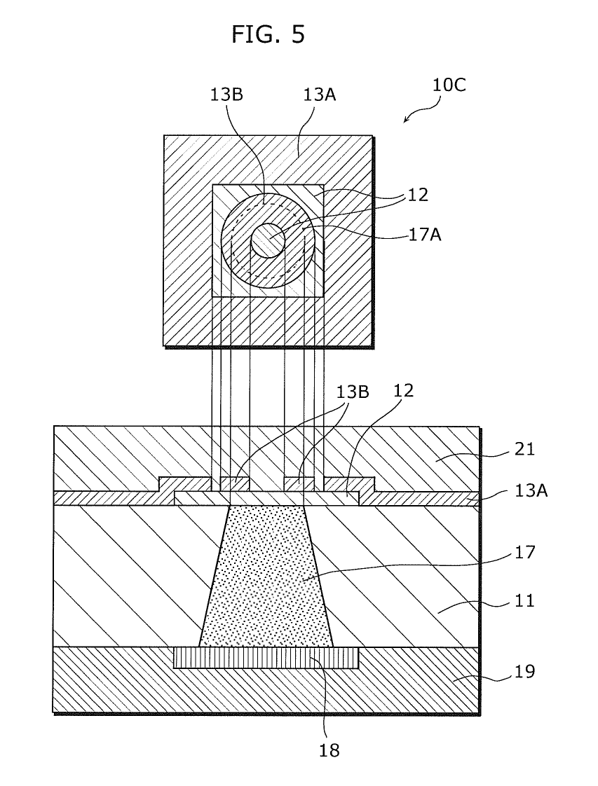

FIG. 3, FIG. 4, and FIG. 5 are each a set of a top view and a cross-sectional view illustrating a specific configuration of the second protective films 13B of the semiconductor device 10 according to Embodiment 1. In view of differences in configurations of the second protective films 13B, the semiconductor device 10 shown in FIG. 3, FIG. 4, and FIG. 5 are hereinafter referred to as a semiconductor device 10A, 10B, and 10C, respectively.

In any of the semiconductor devices 10A, 10B, and 10C, each of the second protective film 13B can be formed apart from the first protective film 13A, on corresponding one of the internal electrodes 12 in a manner such that the second protective film 13B is larger, in area, than an area 17A where the through electrode 17 is in contact with the back surface of the internal electrode 12 (the area indicated by a dashed line, hereinafter referred to as an area 17A in brief).

In the semiconductor device 10A shown in FIG. 3, the second protective film 13B is circular in shape and has a diameter larger than the maximum diameter of the area 17A.

In the semiconductor device 10B shown in FIG. 4, the second protective film 13B is a square having sides longer than the maximum diameter of the area 17A.

Note that although the second protective film 13B is a square, it may have another polygonal shape. It is preferable that second protective film 13B having any polygonal shape has a maximum diameter longer than the maximum diameter of the area 17A.

In the semiconductor device 10C shown in FIG. 5, the second protective film 13B is annular in shape and has an external diameter larger than the diameter of the area 17A and an internal diameter smaller than the diameter of the area 17A.

The second protective film 13B having any of such shapes and sizes is formed so that the second protective film 13B covers the area 17A on the top surface of the internal electrode 12 as shown in FIG. 3, FIG. 4, and FIG. 5.

In such configuration, when stress produced in steps after forming of the through electrode 107 or stress due to environmental load, such as heat in an environment of actual use of the semiconductor device 10, causes stress concentration on the contact between the through electrode 17 and the internal electrode 12, the second protective film 13B prevents deformation of the internal electrode 12, thereby preventing breaking, cracking, and peel-off of the internal electrode 12.

Specifically, because stress concentrates most on the peripheral part of the area 17A, the second protective film 13B formed to cover the peripheral part on the top surface of the internal electrode 12 reinforces the internal electrode 12.

In addition, the clearance, which is formed between the first protective film 13A and the second protective film 13B by forming them apart from each other, relaxes stress concentration on the internal electrode 12 and stress due to deformation of the internal electrode 12, thereby ensuring prevention of breaking, cracking, and peel-off of the internal electrode 12.

(Method of Manufacturing the Semiconductor Device)

The semiconductor device 10 having the above structure is manufactured through the following steps.

(Step 1) Prepare semiconductor elements in which a plurality of internal electrodes 12 is provided on the top surface of the semiconductor substrate 11.

(Step 2) Form the first protective film 13A which has openings selectively on each of the internal electrodes 12 provided on the top surface of the semiconductor substrate 11.

(Step 3) Form the second protective films 13B on a part of the top surface of each of the internal electrodes 12 and in the openings of the first protective film 13A in a manner such that the second protective films 13B are formed apart from the first protective film 13A. The steps 2 and 3 may be carried out at once.

(Step 4) Form through holes which penetrate through the semiconductor substrate 11 in the thickness direction of the semiconductor substrate 11 to reach the back surface of each of the internal electrode 12.

(Step 5) Form the through electrode 17 in each of the through holes in a manner such that the through electrode 17 extends from the inside of the through hole up to the top surface of the semiconductor substrate 11.

(Step 6) Form the metal wiring 18 on the back surface of the semiconductor substrate 11 in a manner such that the metal wiring 18 contacts with the through electrode 17 at the back surface of the semiconductor substrate 11.

(Step 7) Form the insulating layer 19 on the back surface of the semiconductor substrate 11 in a manner such that the insulating layer 19 covers the top surface of metal wiring 18.

(Step 8) Form openings in the insulating layer 19 selectively in the parts each corresponding to the metal wiring 18. The external electrode 20, which electrically connects to the metal wiring 18, is formed in each of the openings in the insulating layer 19 by a solder ball mounting method using flux, a solder paste printing method, or an electroplating method. The external electrode 20 is made of, for example, a lead-free solder material having a composition of Sn—Ag—Cu.

The semiconductor device 10 shown in FIG. 2 is thus manufactured through these steps.

(Detailed Structure of the Main Part According to Variations)

In the above-described semiconductor device 10, the second protective films 13B are formed apart from the first protective film 13A, on the internal electrodes 12, in order to increase the durability of the internal electrode 12 against stress concentration of the through electrode 17 on the internal electrode 12.

In the above configuration, the possibility that the second protective films 13B and the internal electrodes 12 are broken to cause breaking, cracking, or peel-off is reduced. However, the second protective films 13B may fail to prevent deformation of the internal electrodes 12 due to stress concentration, which leads to breaking, cracking, or peel-off of the internal electrodes 12.

The following will describe variations of Embodiment 1 in which not only is the possibility that the second protective films 13B and the internal electrode 12 are broken is reduced, but also the durability of the second protective films 13B against deformation of the internal electrodes 12 increased.

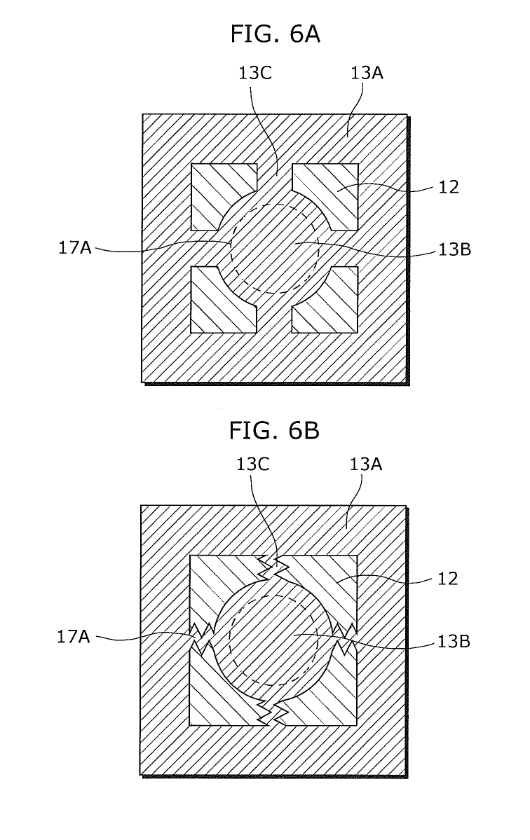

FIG. 6(A) and FIG. 6(B) are top views illustrating specific forms of the second protective films 13B and third protective films 13C according to variations of the first embodiment, respectively.

In either case, the third protective films 13C are formed on the internal electrode 12 so that the third protective films 13C fill a part of the clearance between the first protective film 13A and the second protective film 13B. Referring to FIG. 6(B), each of the third protective films 13C has a wave shape.

Here, the third protective films 13C may be made of an inorganic material such as SiN or an organic material.

The third protective film 13C may be formed in a step independent from one or both of the steps to form the first protective film 13A and the second protective film 13B. Alternatively, the third protective film 13C may be formed in the steps through which the first protective film 13A and the second protective film are formed.

In such configuration, the third protective films 13C, which fill part of the clearance between the first protective film 13A and the second protective film 13B, not only allow the clearance remaining between the first protective film 13A and the second protective film 13B to relax stress concentration on the internal electrode 12 and stress due to deformation of the internal electrode 12, but also transmit forces to prevent deformation of the internal electrode 12 from the first protective film 13A to the second protective film 13B when stress concentration occurs, and further prevents separation and fall-out of the through electrode toward the second main surface of the semiconductor substrate.

In addition, the third protective films 13C have such a wave shape as shown in FIG. 6(B) that the stress exerted on the third protective films 13C is further relaxed.

As described above, in the semiconductor device according to the first embodiment, the characteristic shape of the protective film formed on the internal electrode increases durability of the semiconductor device against stress concentration in the wafer-level CSP, thus contributing to reduction of the size, thickness, and weight of electronic apparatuses, and to improvement in performance.

### Embodiment 2

The following will describe a semiconductor device according to Embodiment 2 with reference to the drawings.

(Structure of the Semiconductor Device)

The semiconductor device according to Embodiment 2 has a cross-section structure identical to that of the semiconductor device 10 shown in FIG. 2 according to Embodiment 2, but differs from it in that the first protective film 13A and the second protective film 13B are integrated and formed, but not on a part of the internal electrode 12. In the description of the semiconductor device according to Embodiment 2, the first protective film 13A and the second protective film 13B are referred to as a protective film 13 without distinction between them. The components described in Embodiment 1 are denoted with the same reference numerals, and thus description thereof is omitted.

### (Detailed Structure of Main Part)

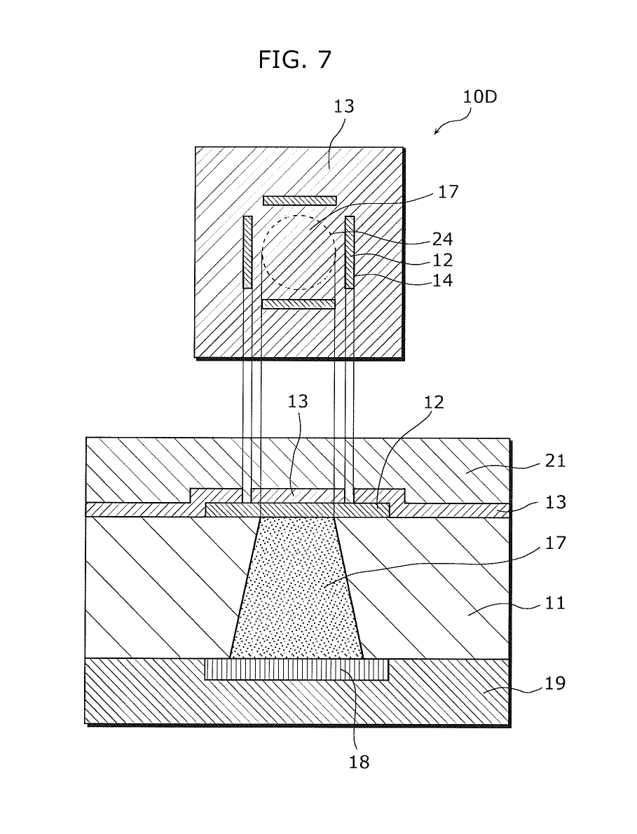

The following will describe specific configurations of the protective film 13 in semiconductor devices 10D and 10E according to Embodiment 2 with reference to FIG. 7 to FIG. 9. For illustrative purposes, the part which is located on the internal electrode 12 and not provided with the protective film 13 is referred to as an opening 14.

FIG. 7 is a set of a top view and a cross-sectional view illustrating a specific configuration of the protective film 13 of the semiconductor device 10D.

Referring to FIG. 7, four openings 14 are formed outside of the contact area 24, which is an area where the through electrode 17 contacts with the internal electrode 12 (that is, in positions surrounding the contact area 24 in the top view). Each of the openings 14 is rectangular in shape. Note that the bonding layer 21 is not shown in the top view of FIG. 7 to show the configuration below the bonding layer 21.

In this configuration, when stress produced in steps after forming of the through electrode 17 or stress due to environmental load, such as heat or external stress in an environment of actual use of the semiconductor device 10D, causes stress concentration on the contact area 24, deformation of the internal electrode 12 is prevented, thereby preventing breaking, cracking, and peel-off of the internal electrode 12.

Specifically, because stress concentrates most on the peripheral part of the contact area 24, the protective film 13 formed to fully cover the peripheral part reinforces the internal electrode 12. In addition, the openings 14, which are formed in the protective film 13, relax stress concentration on the internal electrode 12 and stress due to deformation of the internal electrode 12, thereby ensuring prevention of breaking, cracking, and peel-off of the internal electrode 12.

In addition, even when stress due to environmental load, such as heat or external stress produced in an environment of actual use of the semiconductor device 10D, is exerted on the through electrode 17 or the metal wiring 18 to cause fall-out of the through electrode 17 in the direction to the back surface of the semiconductor substrate 11, the adhesion between the protective film 13 and the internal electrode 12 in the area other than the openings 14 prevents the detachment (fall-out) of the through electrode 17, thereby ensuring highly reliable connection.

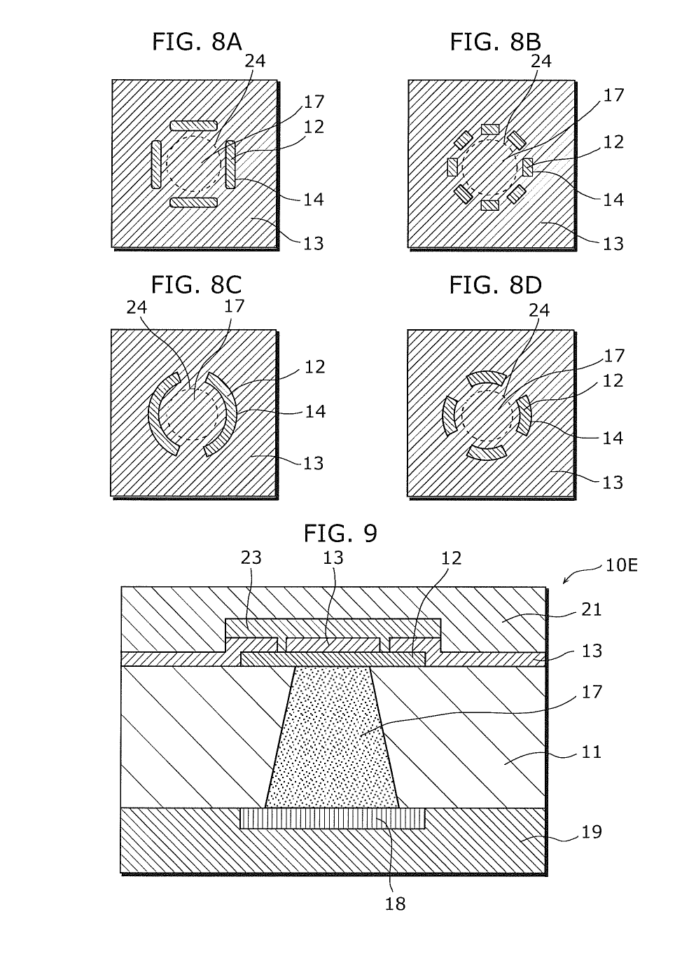

FIG. 8(A) to FIG. 8(D) are top views illustrating other configurations of the openings 14.

Compared to the rectangles shown in FIG. 7, the openings 14 shown in FIG. 8(a) have such rounded corners that the stress concentration on the corners of the opening 14 are relaxed.

In FIG. 8(B), the openings 14 each of which is smaller than that in FIG. 8(A) are formed in a manner such that the ratio between the total area of the openings 14 and the total area of the protective film 13 between the adjacent openings 14 is close to 1 for the purpose of balancing the effect on relaxation of stress and the reinforcing effect (prevention of the fall-out of the through electrode 17) of the protective film 13.

Each of the openings 14 shown in FIG. 8(A) and FIG. 8(B) may be oval or circular in shape. Such shapes also produce the similar effect as the rectangles with rounded corners.

In FIG. 8(C), part of the contour of each of the openings 14 is arched along the through electrode 17. Such shape produces an effect that stress is relaxed most effectively in the peripheral part of the contact area 24 on which the stress concentrates more than on any other part.

In FIG. 8(D), the openings 14 each of which is smaller than that in FIG. 8(C) are formed so that the ratio between the total area of the openings 14 and the total area of the protective film 13 between the openings 14 is close to 1 for the purpose of balancing the effect on relaxation of stress and the reinforcing effect (prevention of the fall-out of the through electrode 17) of the protective film 13.

The following will describe a semiconductor device 10E according to variations of Embodiment 2.

FIG. 9 is a cross-sectional view illustrating a configuration of the main part of the semiconductor device 10E according to the variation of Embodiment 2. In the semiconductor device 10E shown in FIG. 9, another protective film 23 is formed above the internal electrode 12 with the protective film 13 interposed therebetween. The internal electrode 12 and the protective film 23 are directly connected to each other in the openings 14.

In this configuration, the reinforcing effect of the semiconductor device 10E is enhanced in comparison with the configurations shown in FIG. 7 and FIG. 8. The protective film 23 may be made of either an organic material or an inorganic material. When protective film 23 is made of low-elasticity resin, which is an inorganic material, reinforcing effect and stress-relaxing effect are further enhanced.

As described above, the semiconductor devices 10D and 10E shown in FIG. 7 to FIG. 9 are provided with a protective film 13 having the openings 14, and the semiconductor device 10E is further provided with the protective film 23 in addition to the protective film 13.

In this configuration, when stress generated in steps after forming of the through electrode 17 or stress due to environmental load, such as heat in an environment of actual use of the semiconductor device 10D or 10E, causes stress concentration on the contact area 24, deformation of the internal electrode 12 is prevented, thereby preventing breaking, cracking, and peel-off of the semiconductor device 10D.

In addition, even when stress is exerted on the through electrode 17 or the metal wiring 18 to cause fall-out of the through electrode 17 in the direction to the back surface of the semiconductor substrate 11, the detachment (fall-out) of the through electrode 17 is prevented, thereby ensuring highly reliable connection.

The protective film 23 may be formed above the internal electrode 12 of the semiconductor devices 10A to 10C shown in FIG. 3, FIG. 4, and FIG. 5 with the protective film 13 interposed between the internal electrode 12 and the protective film 23 in the same manner as in the semiconductor device 10E. The protective film 23 formed in the semiconductor devices 10A to 10C is directly connected to the internal electrode 12 in the clearance between the first protective film 13A and the second protective film 13B, producing the reinforcing effect against stress.

The following will describe a semiconductor device 10F according to another variation to the above embodiments.

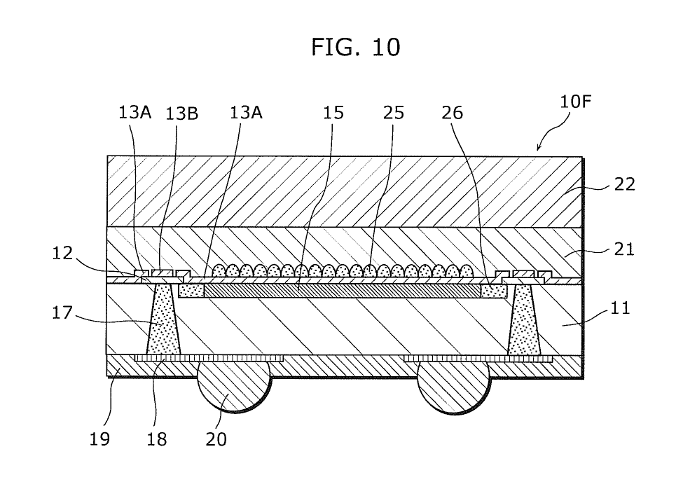

FIG. 10 is a cross-sectional view indicating a structure of the semiconductor device according to an exemplary embodiment. Here, a case is assumed in which the semiconductor device is applied to an optical device such as an image sensor. In the semiconductor device 10F shown in FIG. 10, an imaging area 15 is formed on the semiconductor substrate 11, and a protective film 13A is formed to cover the imaging area 15. Microlenses are formed above the imaging area 15, with the protective film 13A interposed between the imaging area 15 and the microlenses 25. As shown in FIG. 11, the bonding layer 21 may includes a hollow portion 200 between the imaging area 15 and the transparent substrate 22.

In addition, in an area surrounding the imaging area 15, through electrodes 17 pass through the semiconductor substrate 11 in the thickness direction of the imaging area 15. On the top surface of the semiconductor substrate 11, internal electrodes 12 are provided in a manner such that the internal electrodes 12 are electrically connected to the through electrodes 17. In addition, a first protective film 13A is formed so as to cover the first main surface except a part of each of the internal electrode 12. On the part where the internal electrode is not covered with the first protective film 13A, a second protective film 13B is formed apart from the first protective film 13A.

Here, in the present embodiment, the first protective film 13A covering the first main surface except a part of each of the internal electrodes 12, also covers the imaging area 15.

The semiconductor device 10F having the above structure may be manufactured through the following steps:

(Step 1) Prepare semiconductor elements in which a plurality of internal electrodes 12 is provided on the top surface of the semiconductor substrate 11.

(Step 2) Form the first protective film 13A which has openings selectively on each of the internal electrodes 12 and covers the top surface of the semiconductor substrate 11 including the imaging area 15.

(Step 3) Form the second protective film 13B on a part of the top surface of each of the internal electrodes 12 and in the openings of the first protective film 13A in a manner such that the second protective film 13B is formed apart from the first protective film 13A. The steps 2 and 3 may be carried out at once.

(Step 4) Form microlenses 25 above the imaging area 15, with the first protective film 13A interposed between the imaging area 15 and the microlenses 25.

(Step 5) Form through holes which pass through the semiconductor substrate 11 in the thickness direction of the semiconductor substrate 11 to reach the back surface of the internal electrode 12.

(Step 6) Form the through electrode 17 in each of the through holes in a manner such that the through electrode 17 extends from the inside of the through hole up to the top surface of the semiconductor substrate 11.

(Step 7) Form the metal wiring 18 on the back surface of the semiconductor substrate 11 in a manner such that the metal wiring 18 contacts with the through electrode 17 at the back surface of the semiconductor substrate 11.

(Step 8) Form the insulating layer 19 on the back surface of the semiconductor substrate 11 in a manner such that the insulating layer 19 covers the top surface of metal wiring 18.

(Step 7) Provide openings in the insulating layer 19 selectively in the parts each corresponding to the metal wiring 18. The external electrode 20, which electrically connects to the metal wiring 18, is formed in each of openings in the insulating layer 19 by a solder ball mounting method using flux, a solder paste printing method, or an electroplating method. The external electrode 20 is made of, for example, a lead-free solder material having a composition of Sn—Ag—Cu.

(Step 10) Form a transparent substrate 22 above the top surface of the semiconductor substrate 11, with the bonding layer 21 interposed between the transparent substrate 22 and the semiconductor substrate 11.

(Step 11) Dice the semiconductor substrate 11, by cutting through the transparent substrate 22 and the bonding layer 21.

The semiconductor device 10F shown in FIG. 10 is thus manufactured through the steps. However, it should be understood that the manufacturing method is not limited to the above method or the above order of the steps.

In this configuration, even when stress generated in steps after forming of the through electrode 17 or stress due to environmental load, such as heat in an environment of actual use of the semiconductor device 10D or 10E, causes stress concentration on the contact between the through electrode 17 and the internal electrode 12, deformation of the internal electrode 12 is prevented, thereby preventing breaking, cracking, and peel-off of the internal electrode 12.

In addition, even when stress is exerted on the through electrode 17 or the metal wiring 18 to cause fall-out of the through electrode 17 in the direction to the back surface of the semiconductor substrate 11, the detachment (fall-out) of the through electrode 17 is prevented, thereby ensuring highly reliable connection.

Note that the semiconductor device according to Embodiment 2 may include protective films having configurations shown in any of FIG. 3 to FIG. 9.

As described above, in the semiconductor device according to the various embodiments, the characteristic shapes of the protective films formed on the internal electrode increase durability of the semiconductor device against stress concentration in the wafer-level CSP, thus contributing to reduction of the size, thickness, and weight of electronic apparatuses, and to improvement in performance.

Therefore, the present disclosure concerns a semiconductor device, comprising: a semiconductor substrate; an internal electrode provided on a first surface of said semiconductor substrate; a metal wiring formed on a second surface of said semiconductor substrate opposite to the first surface; a through electrode penetrating through said semiconductor substrate and electrically connecting said internal electrode with said metal wiring; a first protective film formed on the first surface of the substrate and a region of the internal electrode so that a first portion of the internal electrode is uncovered by the first protective film; and a second protective film formed on a region of the uncovered first portion of the internal electrode so that a second portion of the internal electrode is uncovered by the second protective film.

The present disclosure also concerns a semiconductor device, comprising: a semiconductor substrate; an internal electrode provided in a part of a first surface of said semiconductor substrate; a metal wiring formed on a second surface of said semiconductor substrate and electrically connected to said through electrode, the second surface being on a side of said semiconductor substrate opposite the first surface; a through electrode penetrating through said semiconductor substrate in a thickness direction of said semiconductor substrate, the through electrode electrically connected to the internal electrode and the metal wiring; a first protective film covering the first main surface and a portion of said internal electrode; wherein a plurality of openings is formed in said protective film on said internal electrode.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The semiconductor device according to the various embodiments is applicable particularly to optical devices (solid-state imaging elements as well as a variety of semiconductor devices, such as photodiodes, laser modules, and various modules), and to semiconductor devices including other LSIs, memories, vertical devices (for example, diodes, transistors), and interposers.

What is claimed is:

1. A semiconductor device, comprising:
a semiconductor substrate;
an internal electrode provided on a first surface of said semiconductor substrate;
a metal wiring formed on a second surface of said semiconductor substrate opposite to the first surface;
a through electrode penetrating through said semiconductor substrate and electrically connecting said internal electrode with said metal wiring;
a first protective film formed on the first surface of the substrate and a region of the internal electrode so that a first portion of the internal electrode is uncovered by the first protective film; and
a second protective film formed on a region of the uncovered first portion of the internal electrode so that a second portion of the internal electrode is uncovered by the second protective film.

2. The semiconductor device according to claim 1,
wherein a surface area of said second protective film is greater than a contact area between said through electrode and said internal electrode.

3. The semiconductor device according to claim 1,
wherein said second protective film is circular in shape

4. The semiconductor device according to claim 1,
wherein said second protective film is polygonal in shape.

5. The semiconductor device according to claim 1,
wherein said second protective film is annular in shape and has an external diameter larger than a diameter of a contact area between said through electrode and said internal electrode and an internal diameter smaller than the diameter of the contact area.

6. The semiconductor device according to claim 1,
wherein each of said first protective film and said second protective film includes an inorganic material.

7. The semiconductor device according to claim 1,
wherein said first protective film includes an inorganic material and said second protective film includes an organic material.

8. The semiconductor device according to claim 1, further comprising
a third protective film formed on said internal electrode so as to fill part of a clearance between said first protective film and said second protective film.

9. The semiconductor device according to claim 1, further comprising
an insulating layer covering a first portion of the second main surface to uncover a part of said metal wiring.

10. The semiconductor device according to claim 9, further comprising
an external electrode provided on the uncovered part of said metal wiring and electrically connected to said metal wiring.

11. An electronic apparatus comprising
the semiconductor device according to claim 1 electrically connected to wiring provided on a surface of a circuit board through one of the metal wiring and the external electrode.

12. A semiconductor device, comprising:
a semiconductor substrate;
an internal electrode provided in a part of a first surface of said semiconductor substrate;
a metal wiring formed on a second surface of said semiconductor substrate, the second surface being on a side of said semiconductor substrate opposite the first surface;
a through electrode penetrating through said semiconductor substrate, the through electrode electrically connected to the internal electrode and the metal wiring; and
a protective film covering the first main surface and a portion of said internal electrode; and
wherein a plurality of openings is formed in said protective film on said internal electrode.

13. The semiconductor device according to claim 12,
wherein said plurality of openings is formed outside of a contact area between said through electrode and said internal electrode.

14. The semiconductor device according to claim 12,
wherein each of said openings is circular in shape.

15. The semiconductor device according to claim 12,
wherein each of said openings has a polygonal shape.

16. The semiconductor device according to claim 15,
wherein each of said openings having the polygonal shape has rounded corners.

17. The semiconductor device according to claim 12,
wherein each of said openings has an arched contour.

18. The semiconductor device according to claim 12,
wherein, on said internal electrode, the number of said openings in said protective film is two or more.

19. The semiconductor device according to claim 12,
wherein, above said internal electrode, another protective film is formed on said protective film.

20. The semiconductor device according to claim 19,
wherein said another protective film contacts said internal electrode through said plurality of openings.

21. The semiconductor device according to claim 19,
wherein said another protective film includes an organic material.

22. The semiconductor device according to claim 19,
wherein said another protective film includes an inorganic material.

23. The semiconductor device according to claim 12, further comprising
an insulating layer covering a first portion of the second main to uncover a part of said metal wiring.

24. The semiconductor device according to claim 23, further comprising
an external electrode provided on the uncovered part of said metal wiring and electrically connected to said metal wiring.

25. An electronic apparatus comprising
the semiconductor device according to claim 12 electrically connected to wiring formed on a surface of a circuit board through one of said metal wiring and said external electrode.
